(19) United States
(12) Patent Application Publication
(10) Pub. No.: US 2025/0072208 A1
(43) Pub. Date: Feb. 27, 2025

(54) DISPLAY DEVICE AND METHOD OF MANUFACTURING THE SAME

(71) Applicant: Samsung Display Co., Ltd., Yongin-si (KR)

(72) Inventors: Changyeong Song, Yongin-si (KR); Yeonguk Kim, Yongin-si (KR); Heeyeon Park, Yongin-si (KR); Yongchan Ju, Yongin-si (KR); Jaeheung Ha, Yongin-si (KR)

(21) Appl. No.: 18/789,699

(22) Filed: Jul. 31, 2024

(30) Foreign Application Priority Data
Aug. 22, 2023 (KR) 10-2023-0110134

(51) Int. Cl. H10K 50/844; B82Y 20/00; H10K 50/854

(52) U.S. Cl. CPC H10K 50/844; B82Y 20/00; H10K 50/854

(57) ABSTRACT

A display device includes a substrate including a display area and a peripheral area disposed outside the display area, a light-emitting element disposed on the display area of the substrate, and an encapsulation member disposed on the light-emitting element and including at least one inorganic encapsulation layer and at least one organic encapsulation layer. An organic encapsulation layer of the at least one organic encapsulation layer includes surface-enhanced Raman scattering (SERS) active nanoparticles.

### CROSS-REFERENCE TO RELATED APPLICATION

This application is based on and claims priority under 35 U.S.C. § 119 to Korean Patent Application No. 10-2023-0110134, filed on Aug. 22, 2023, in the Korean Intellectual Property Office, the disclosure of which is incorporated by reference herein in its entirety.

### BACKGROUND

### 1. Field

One or more embodiments relate to a display device and a method of manufacturing the same.

### 2. Description of the Related Art

Display devices visually display data. Recently, display devices have been used in a greater variety of ways. In addition, display devices have become thinner and lighter in weight, and thus, their range of use has widened.

For example, in the case of an organic light-emitting display device, in order to manufacture a thin and light display device, an emission area may be encapsulated by using, instead of an encapsulation substrate formed of a glass material, a thin-film encapsulation layer including at least one inorganic encapsulation layer and at least one organic encapsulation layer.

The organic encapsulation layer may planarize an upper surface of a display area of the organic light-emitting display device by covering the display area and may prevent cracking of the inorganic encapsulation layer by covering a portion of a peripheral area of the organic light-emitting display device.

In the case where the organic encapsulation layer is coated using an inkjet method, there may be a need to check whether a material of the organic encapsulation layer discharged via an inkjet process has been disposed at a target location on the peripheral area.

### SUMMARY

One or more embodiments allow monitoring of a disposition location of an organic encapsulation layer via Raman detection by adding surface-enhanced Raman scattering (SERS) active nanoparticles to an organic encapsulation layer. However, such a technical feature is an example, and one or more embodiments are not limited thereto.

Additional aspects will be set forth in part in the description which follows and, in part, will be apparent from the description, or may be learned by practice of the presented embodiments of the disclosure.

According to one or more embodiments, a display device includes a substrate including a display area and a peripheral area disposed outside the display area, a light-emitting element disposed on the display area of the substrate, and an encapsulation member disposed on the light-emitting element and including at least one inorganic encapsulation layer and at least one organic encapsulation layer. An organic encapsulation layer of the at least one organic encapsulation layer includes surface-enhanced Raman scattering (SERS) active nanoparticles.

The SERS active nanoparticles may be metal nanoparticles on the surface of which a Raman label compound is adsorbed, wherein a size of each of the metal nanoparticles may be at least about 1 nm but not more than about 20 nm.

The metal nanoparticles may include gold (Au), silver (Ag), or copper (Cu).

The Raman label compound may include an aromatic ring.

The Raman label compound may include at least one of thiophenol, 4-Mercaptophenol, 4-nitrothiophenol, 4-aminothiophenol, 4-mercaptophenylboronic acid, 4-mercaptobenzoic acid, or pyridine-4-thiol.

Based on a total weight of the organic encapsulation layer, a content of the SERS active nanoparticles may be greater than 0 wt % but not more than 5 wt %.

A viscosity of the organic encapsulation layer may range from 1 cP to 50 cP.

The at least one inorganic encapsulation layer may include a first inorganic encapsulation layer and a second inorganic encapsulation layer. The organic encapsulation layer may be disposed on the first inorganic encapsulation layer, and the second inorganic encapsulation layer may be disposed on the organic encapsulation layer.

The display device may further include a dam portion disposed on the peripheral area, wherein the first inorganic encapsulation layer and the second inorganic encapsulation layer may be in contact with each other on the dam portion.

The display device may further include a valley portion disposed on the peripheral area and disposed between the dam portion and the display area, wherein the organic encapsulation layer may overlap the valley portion.

The light-emitting element may include a pixel electrode, an emission layer on the pixel electrode, and an opposite electrode on the emission layer.

According to one or more embodiments, a display device includes a substrate, a light-emitting element disposed on the substrate and including a pixel electrode, an emission layer on the pixel electrode, and an opposite electrode on the emission layer, and an encapsulation member disposed on the light-emitting element. The encapsulation member includes a first inorganic encapsulation layer, an organic encapsulation layer on the first inorganic encapsulation layer, and a second inorganic encapsulation layer on the organic encapsulation layer. The organic encapsulation layer includes surface-enhanced Raman scattering (SERS) active nanoparticles in which metal nanoparticles are surface-treated with a Raman label compound, wherein the Raman label compound includes an aromatic ring.

A size of each of the metal nanoparticles may be 20 nm or less.

The metal nanoparticles may include gold (Au), silver (Ag), or copper (Cu).

The Raman label compound may include at least one of thiophenol, 4-Mercaptophenol, 4-nitrothiophenol, 4-aminothiophenol, 4-mercaptophenylboronic acid, 4-mercaptobenzoic acid, or pyridine-4-thiol.

Based on a total weight of the organic encapsulation layer, a content of the SERS active nanoparticles may be greater than 0 wt % but not more than 5 wt %.

According to one or more embodiments, a method of manufacturing a display device includes forming a first inorganic encapsulation layer on a light-emitting element, forming an organic encapsulation layer on the first inorganic encapsulation layer, the organic encapsulation layer including surface-enhanced Raman scattering (SERS) active nanoparticles, testing a disposition location of the organic encapsulation layer by using Raman spectroscopy, and forming a second inorganic encapsulation layer on the organic encapsulation layer.

The SERS active nanoparticles may be formed by surface-treating metal nanoparticles with a Raman label compound, wherein a size of each of the metal nanoparticles may be 20 nm or less.

The Raman label compound may include an aromatic ring.

The Raman label compound may include at least one of thiophenol, 4-Mercaptophenol, 4-nitrothiophenol, 4-aminothiophenol, 4-mercaptophenylboronic acid, 4-mercaptobenzoic acid, or pyridine-4-thiol.

### BRIEF DESCRIPTION OF THE DRAWINGS

The above and other aspects and features of certain embodiments of the disclosure will be more apparent from the following description taken in conjunction with the accompanying drawings.

FIG. 1 is a schematic plan view of a display device according to an embodiment.

FIGS. 2A and 2B are examples of an equivalent circuit diagram of a sub-pixel included in a display device according to an embodiment.

FIG. 3 is a schematic cross-sectional view of a display device according to an embodiment, taken along a line I-I′ of FIG. 1.

FIG. 4 is a schematic enlarged view of an organic encapsulation layer of a display device.

FIG. 5 is a flowchart of a method of manufacturing of a display device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof are omitted.

While such terms as “first” and “second” may be used to describe various elements, such elements must not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

When an embodiment may be implemented differently, a certain process order may be performed differently from the described order. For example, two consecutively described processes may be performed substantially at the same time or performed in an order opposite to the described order.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

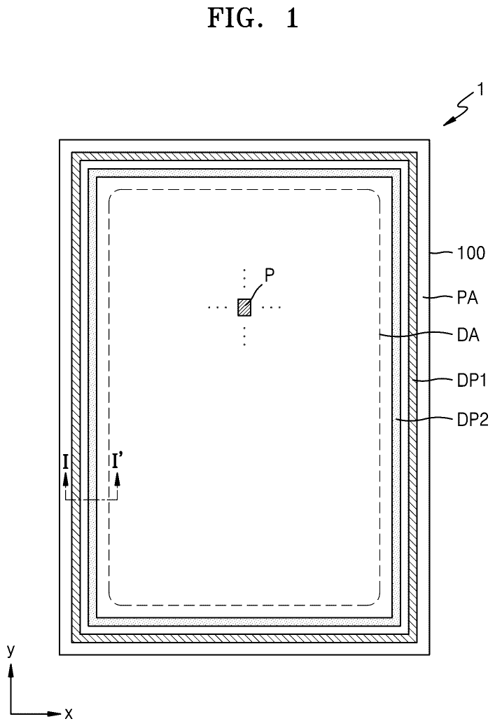

FIG. 1 is a schematic plan view of a display device 1 according to an embodiment.

Referring to FIG. 1, the display device 1 may display an image. The display device 1 may include a display area DA and a peripheral area PA. In an embodiment, the display area DA and the peripheral area PA may be defined on a substrate 100. In other words, the substrate 100 may include the display area DA and the peripheral area PA.

The display device 1 may provide an image through a plurality of sub-pixels P disposed on the display area DA. Each of the sub-pixels P of the display device 1 is an area capable of emitting light of a certain color, and the display device 1 may display an image by using light emitted from the plurality of sub-pixels P. For example, the sub-pixel P may emit red, green, or blue light. As another example, the sub-pixel P may emit red, green, blue, or white light.

The peripheral area PA may be disposed outside the display area DA. For example, the peripheral area PA may at least partially surround the display area DA. In an embodiment, the peripheral area PA may entirely surround the display area DA. The peripheral area PA, which is an area where sub-pixels P are not disposed, may be an area where no image is provided.

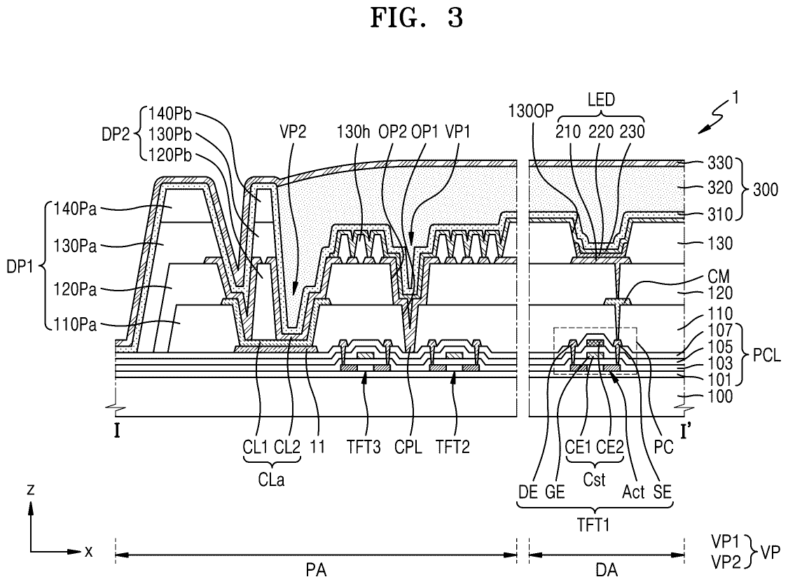

A first dam portion DP1 and a second dam portion DP2 may be disposed on the peripheral area PA. The first dam portion DP1 and the second dam portion DP2 may surround the display area DA. The first dam portion DP1 and the second dam portion DP2 may be apart from each other. Although, in the present embodiment, the number of dam portions surrounding the display area DA is shown as two, one or more embodiments are not limited thereto, and the number may be variously changed to one or two or more. The first dam portion DP1 and the second dam portion DP2 may serve as a dam that blocks an organic material from flowing towards the edge of the substrate 100 when an organic encapsulation layer 320 (refer to FIG. 3) constituting, e.g., included in, an encapsulation member 300 (refer to FIG. 3) is formed via an inkjet process, and thus, may prevent an edge tail from being formed at the edge of the substrate 100 by the organic encapsulation layer 320.

As shown in FIG. 1, the display area DA may have a polygonal shape including a quadrilateral shape. For example, the display area DA may have a rectangular shape having a horizontal length greater than a vertical length, a rectangular shape having a horizontal length less than a vertical length, or a square shape. Alternatively, the display area DA may have various shapes, such as an oval shape or a circular shape.

The display device 1 may be included in a mobile phone, a television, a billboard, a monitor, a tablet personal computer (PC), a notebook computer, etc.

The display device 1 is a device for displaying an image, and may be a liquid crystal display, an electrophoretic display, an organic light-emitting display, an inorganic light-emitting display, a field emission display, a surface-conduction electron-emitter display, a plasma display, a cathode ray display, or the like.

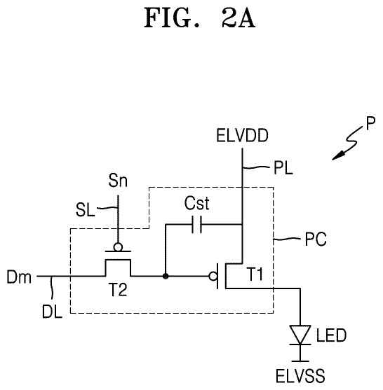

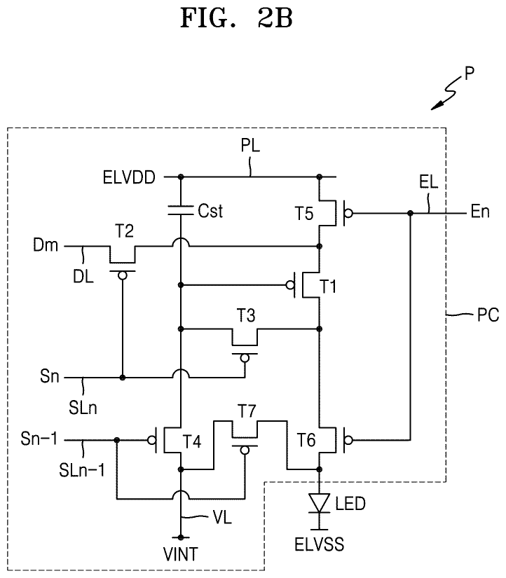

FIGS. 2A and 2B are examples of an equivalent circuit diagram of the sub-pixel P included in the display device 1 according to an embodiment.

Paying particular attention to FIG. 2A, each sub-pixel P may include a pixel circuit PC connected to a scan line SL and a data line DL and a light-emitting element LED connected to the pixel circuit PC. For example, the light-emitting element LED may be an organic light-emitting diode.

The pixel circuit PC may include a driving thin-film transistor T1, a switching thin-film transistor T2, and a storage capacitor Cst.

The switching thin-film transistor T2 is configured to transfer a data signal Dm input through the data line DL to the driving thin-film transistor T1 according to a scan signal Sn input through the scan line SL.

The storage capacitor Cst is connected to the switching thin-film transistor T2 and a driving voltage line PL and stores a voltage corresponding to a difference between a voltage received from the switching thin-film transistor T2 and a first power voltage ELVDD (or referred to as a driving voltage) supplied to the driving voltage line PL.

The driving thin-film transistor T1 is connected to the driving voltage line PL and the storage capacitor Cst, and may be configured to control a driving current flowing through the light-emitting element LED from the driving voltage line PL, in response to a voltage value stored in the storage capacitor Cst. The light-emitting element LED may emit light having certain brightness according to the driving current.

Although FIG. 2A shows a case where the pixel circuit PC includes two thin-film transistors T1, T2 and one storage capacitor Cst, one or more embodiments are not limited thereto.

Referring to FIG. 2B, the pixel circuit PC may include the driving and switching thin-film transistors T1 and T2, a compensation thin-film transistor T3, a first initialization thin-film transistor T4, a first emission control thin-film transistor T5, a second emission control thin-film transistor T6, and a second initialization thin-film transistor T7.

Although FIG. 2B shows each sub-pixel P including signal lines, for example, a first scan line SLn, a second scan line SLn−1, an emission control line EL, and the data line DL, an initialization voltage line VL, and the driving voltage line PL, one or more embodiments are not limited thereto. In an embodiment, at least one of the signal lines, for example, the first scan line SLn, the second scan line SLn−1, the emission control line EL, and the data line DL, and/or the initialization voltage line VL may be shared with neighboring sub-pixels P.

A drain electrode of the driving thin-film transistor T1 may be electrically connected to the light-emitting element LED via the second emission control thin-film transistor T6. The driving thin-film transistor T1 is configured to receive the data signal Dm according to a switching operation of the switching thin-film transistor T2 and supply a driving current to the light-emitting element LED.

A gate electrode of the switching thin-film transistor T2 is connected to the first scan line SLn, and a source electrode thereof is connected to the data line DL. A drain electrode of the switching thin-film transistor T2 may be connected to a source electrode of the driving thin-film transistor T1 and may also be connected to the driving voltage line PL via the first emission control thin-film transistor T5.

The switching thin-film transistor T2 is turned on according to a first scan signal Sn received through the first scan line SLn and is configured to perform a switching operation for transferring the data signal Dm transmitted through the data line DL to the source electrode of the driving thin-film transistor T1.

A gate electrode of the compensation thin-film transistor T3 may be connected to the first scan line SLn. A source electrode of the compensation thin-film transistor T3 may be connected to the drain electrode of the driving thin-film transistor T1 and may also be connected to a pixel electrode of the light-emitting element LED via the second emission control thin-film transistor T6. A drain electrode of the compensation thin-film transistor T3 may be connected to one electrode of the storage capacitor Cst, a source electrode of the first initialization thin-film transistor T4, and a gate electrode of the driving thin-film transistor T1. The compensation thin-film transistor T3 is turned on according to the first scan signal Sn received through the first scan line SLn and is configured to diode-connect the driving thin-film transistor T1 by connecting the gate electrode and the drain electrode of the driving thin-film transistor T1 to each other.

A gate electrode of the first initialization thin-film transistor T4 may be connected to the second scan line SLn−1 (previous scan line). A drain electrode of the first initialization thin-film transistor T4 may be connected to the initialization voltage line VL. The source electrode of the first initialization thin-film transistor T4 may be connected to the one electrode of the storage capacitor Cst, the drain electrode of the compensation thin-film transistor T3, and the gate electrode of the driving thin-film transistor T1. The first initialization thin-film transistor T4 may be turned on according to a second scan signal Sn−1 received through the second scan line SLn−1 and be configured to perform an initialization operation for initializing a voltage of the gate electrode of the driving thin-film transistor T1 by transferring an initialization voltage VINT to the gate electrode of the driving thin-film transistor T1.

A gate electrode of the first emission control thin-film transistor T5 may be connected to the emission control line EL. A source electrode of the first emission control thin-film transistor T5 may be connected to the driving voltage line PL. A drain electrode of the first emission control thin-film transistor T5 may be connected to the source electrode of the driving thin-film transistor T1 and the drain electrode of the switching thin-film transistor T2.

A gate electrode of the second emission control thin-film transistor T6 may be connected to the emission control line EL. A source electrode of the second emission control thin-film transistor T6 may be connected to the drain electrode of the driving thin-film transistor T1 and the source electrode of the compensation thin-film transistor T3. A drain electrode of the second emission control thin-film transistor T6 may be electrically connected to the pixel electrode of the light-emitting element LED. The first emission control thin-film transistor T5 and the second emission control thin-film transistor T6 are simultaneously turned on according to an emission control signal En received through the emission control line EL, and thus, the first power voltage ELVDD is transferred to the light-emitting element LED and a driving current flows through the light-emitting element LED.

A gate electrode of the second initialization thin-film transistor T7 may be connected to the second scan line SLn−1. A source electrode of the second initialization thin-film transistor T7 may be connected to the pixel electrode of the light-emitting element LED. A drain electrode of the second initialization thin-film transistor T7 may be connected to the initialization voltage line VL. The second initialization thin-film transistor T7 may be turned on according to the second scan signal Sn−1 received through the second scan line SLn−1 and be configured to initialize the pixel electrode of the light-emitting element LED.

Although FIG. 2B shows a case where the first initialization thin-film transistor T4 and the second initialization thin-film transistor T7 are connected to the second scan line SLn−1, one or more embodiments are not limited thereto. In an embodiment, the first initialization thin-film transistor T4 may be connected to the second scan line SLn−1, which is a previous scan line, to operate according to the second scan signal Sn−1, and the second initialization thin-film transistor T7 may be connected to a separate signal line (e.g., a next scan line) to operate according to a signal transmitted to the corresponding scan line.

The other electrode of the storage capacitor Cst may be connected to the driving voltage line PL. The one electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., a cathode) of the light-emitting element LED receives a second power voltage ELVSS (or referred to as a common power voltage). The light-emitting element LED receives a driving current from the driving thin-film transistor T1 and emits light.

The pixel circuit PC is not limited to the numbers of thin-film transistors and storage capacitors and the circuit design described with reference to FIGS. 2A and 2B, and the numbers of thin-film transistors and storage capacitors and the circuit design may be variously changed.

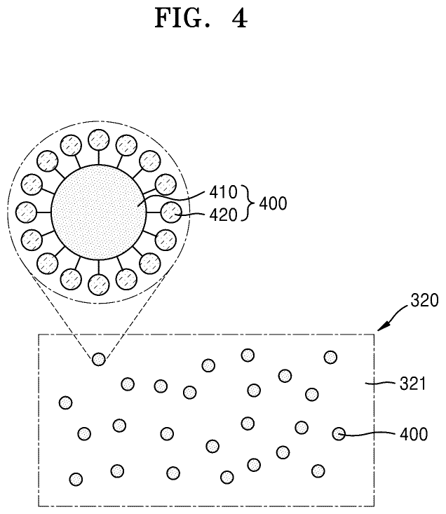

FIG. 3 is a schematic cross-sectional view of the display device 1 according to an embodiment, taken along a line I-I′ of FIG. 1. FIG. 4 is a schematic enlarged view of the organic encapsulation layer 320 of the display device 1.

Referring to FIGS. 3 and 4, the display device 1 may include the substrate 100, a pixel circuit layer PCL, the light-emitting element LED, and the encapsulation member 300. The display device 1 may further include a valley portion VP, the first dam portion DP1, and the second dam portion DP2. The valley portion VP may include a first valley portion VP1 and a second valley portion VP2.

The substrate 100 may include glass. In an embodiment, the substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc. In an embodiment, the substrate 100 may have a multi-layer structure including a base layer and a barrier layer (not shown), the base layer including the above polymer resin. Hereinafter, a case where the substrate 100 includes glass will be mainly described in detail.

The pixel circuit layer PCL may be disposed on the substrate 100. The pixel circuit layer PCL may include a buffer layer 101, a first inorganic insulating layer 103, a second inorganic insulating layer 105, a third inorganic insulating layer 107, the pixel circuit PC including a first thin-film transistor TFT1, a second thin-film transistor TFT2, and a third thin-film transistor TFT3.

The pixel circuit PC may include at least one first thin-film transistor TFT1 and the storage capacitor Cst. The first thin-film transistor TFT1 may be disposed on the display area DA. The first thin-film transistor TFT1 may be, but is not limited to, the driving thin-film transistor T1 of the pixel circuit PC described with reference to FIG. 2A or the second emission control thin-film transistor T6 of the pixel circuit PC described with reference to FIG. 2B.

The second thin-film transistor TFT2 and the third thin-film transistor TFT3 may be disposed on the peripheral area PA. Each of the second thin-film transistor TFT2 and the third thin-film transistor TFT3 may be a thin-film transistor of a driving circuit. For example, the second thin-film transistor TFT2 may be a thin-film transistor of a scan driving circuit, and the third thin-film transistor TFT3 may be a thin-film transistor of an emission control driving circuit.

Each of the first thin-film transistor TFT1, the second thin-film transistor TFT2, and the third thin-film transistor TFT3 may include a semiconductor layer Act, a gate electrode GE, a source electrode SE, and a drain electrode DE.

The buffer layer 101 may be disposed on the substrate 100 to planarize an upper surface of the substrate 100 and block impurities from flowing in from the substrate 100. The buffer layer 101 may include an inorganic insulating material such as silicon oxide (SiOₓ), silicon nitride (SiNₓ), and silicon oxynitride (SiOₓN_{y}). The buffer layer 101 may include a single-layer or multi-layer structure including the above inorganic insulating material.

The semiconductor layer Act may be disposed on the buffer layer 101. The semiconductor layer Act may include an oxide semiconductor and/or a silicon semiconductor. When the semiconductor layer Act includes an oxide semiconductor, the semiconductor layer Act may include, for example, oxide of at least one material selected from the group including indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the semiconductor layer Act may be an InSnZnO (ITZO) semiconductor layer, an InGaZnO (IGZO) semiconductor layer, or the like. When the semiconductor layer Act includes a silicon semiconductor, the semiconductor layer Act may include, for example, amorphous silicon or low temperature poly-silicon (LTPS).

The gate electrode GE may be disposed over the semiconductor layer Act with the first inorganic insulating layer 103 therebetween. The gate electrode GE may overlap a channel region of the semiconductor layer Act. The gate electrode GE may include a low-resistance metal material. For example, the gate electrode GE may have a single-layer or multi-layer structure including one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The gate electrode GE may be connected to a gate line configured to apply an electrical signal to the gate electrode GE.

The first inorganic insulating layer 103 may be disposed on the buffer layer 101. The first inorganic insulating layer 103 may be disposed between the semiconductor layer Act and the gate electrode GE. The first inorganic insulating layer 103 may include, for example, an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ, which may include ZnO and/or ZnO₂).

The second inorganic insulating layer 105 may be disposed on the first inorganic insulating layer 103. The second inorganic insulating layer 105 may cover the gate electrode GE. In a similar way to the first inorganic insulating layer 103, the second inorganic insulating layer 105 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ, which may include ZnO and/or ZnO₂).

An upper electrode CE2 of the storage capacitor Cst may be disposed on the second inorganic insulating layer 105. In an embodiment, the upper electrode CE2 may overlap the gate electrode GE. In this regard, the gate electrode GE and the upper electrode CE2 overlapping each other with the second inorganic insulating layer 105 therebetween may constitute the storage capacitor Cst. That is, the gate electrode GE may serve as a lower electrode CE1 of the storage capacitor Cst. As described above, the storage capacitor Cst and the first thin-film transistor TFT1 may overlap each other. In an embodiment, the storage capacitor Cst and the first thin-film transistor TFT1 may not overlap each other.

The third inorganic insulating layer 107 may be disposed on the second inorganic insulating layer 105. The third inorganic insulating layer 107 may cover the upper electrode CE2. The third inorganic insulating layer 107 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ, which may include ZnO and/or ZnO₂). The third inorganic insulating layer 107 may have a single-layer or multi-layer structure including the above inorganic insulating material.

The source electrode SE and the drain electrode DE may each be disposed on the third inorganic insulating layer 107. The source electrode SE and the drain electrode DE may be electrically connected to the semiconductor layer Act through contact holes formed in the first inorganic insulating layer 103, the second inorganic insulating layer 105, and the third inorganic insulating layer 107. The source electrode SE and the drain electrode DE may include a highly conductive material. At least one of the source electrode SE and the drain electrode DE may include a conductive material including molybdenum (Mo), aluminum (Al), copper (Cu), or titanium (Ti), and may have a multi-layer or single-layer structure including the above material. In an embodiment, at least one of the source electrode SE and the drain electrode DE may have a multi-layer structure of Ti/Al/Ti.

In an embodiment, the display device 1 may further include a power voltage line 11 on the pixel circuit layer PCL. The power voltage line 11 may be disposed on the third inorganic insulating layer 107. The power voltage line 11 may be disposed on the peripheral area PA. The power voltage line 11 may be a wire configured to transmit various signals and/or voltages to be provided to the pixel circuit PC. For example, the power voltage line 11 may be a common power voltage line configured to provide the second power voltage ELVSS (refer to FIGS. 2A and 2B) to each of the sub-pixels P (refer to FIGS. 2A and 2B).

The display device 1 may further include at least one planarization layer disposed on the pixel circuit layer PCL. In an embodiment, the display device 1 may include a first planarization layer 110 and a second planarization layer 120 disposed on the pixel circuit layer PCL.

The first planarization layer 110 may be disposed on the pixel circuit layer PCL. The first planarization layer 110 may cover the pixel circuit PC. The first planarization layer 110 may be disposed on the third inorganic insulating layer 107. The first planarization layer 110 may be disposed on the source electrode SE and the drain electrode DE. The first planarization layer 110 may be disposed on the first thin-film transistor TFT1 in the display area DA and may be disposed on the second and third thin-film transistors TFT2 and TFT3 in the peripheral area PA. The second planarization layer 120 may be disposed on the first planarization layer 110 while covering a connection electrode CM described below.

Each of the first planarization layer 110 and the second planarization layer 120 may include an organic insulating layer. Each of the first planarization layer 110 and the second planarization layer 120 may include an organic material. Each of the first planarization layer 110 and the second planarization layer 120 may include an organic insulating material such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof. The first planarization layer 110 and the second planarization layer 120 may planarize an upper surface of the pixel circuit PC, thereby planarizing a surface on which the light-emitting element LED is to be positioned.

In an embodiment, the display device 1 may further include the connection electrode CM disposed on the first planarization layer 110 in the display area DA. The connection electrode CM may be disposed between the first planarization layer 110 and the second planarization layer 120. The connection electrode CM may include a conductive material including molybdenum (Mo), aluminum (Al), copper (Cu), titanium (Ti), etc., and may have a multi-layer or single-layer structure including the above material. In an embodiment, the connection electrode CM may have a multi-layer structure of Ti/Al/Ti. The second planarization layer 120 may be disposed on the first planarization layer 110 while covering the connection electrode CM.

The light-emitting element LED may be disposed over the pixel circuit layer PCL in the display area DA. The light-emitting element LED may be electrically connected to the pixel circuit PC disposed between the substrate 100 and the light-emitting element LED in a direction (e.g., a direction z) perpendicular to the substrate 100. The light-emitting element LED may be disposed on the second planarization layer 120. The light-emitting element LED may emit red, green, or blue light, or may emit red, green, blue, or white light. A stacked structure of a pixel electrode 210, an intermediate layer 220, and an opposite electrode 230 may constitute one light-emitting element LED.

The light-emitting element LED may be an organic light-emitting diode including an organic emission layer. Alternatively, the light-emitting element LED may be an inorganic light-emitting diode including an inorganic emission layer. The light-emitting diode may have a micro-scale or nano-scale size. For example, the light-emitting diode may be a micro light-emitting diode. Alternatively, the light-emitting diode may be a nanorod light-emitting diode. The nanorod light-emitting diode may include gallium nitride (GaN). In an embodiment, a color conversion layer may be disposed on the nanorod light-emitting diode. The color conversion layer may include quantum dots. Alternatively, the light-emitting diode may be a quantum dot light-emitting diode including a quantum dot emission layer.

The pixel electrode 210 may be disposed on the second planarization layer 120. The pixel electrode 210 may be electrically connected to the connection electrode CM through a contact hole in the second planarization layer 120. In an embodiment, the pixel electrode 210 may include conductive oxide such as indium tin oxide (ITO), indium zinc oxide (IZO), zinc oxide (ZnOₓ, which may include ZnO and/or ZnO₂), indium oxide (In₂O₃), indium gallium oxide (IGO), or aluminum zinc oxide (AZO). In an embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 210 may further include a layer including ITO, IZO, ZnO, or In₂O₃ on/under the above reflective layer. For example, the pixel electrode 210 may have a multi-layer structure of ITO/Ag/ITO.

A pixel-defining layer 130 including an opening 130OP exposing a central portion of the pixel electrode 210 may be disposed on the pixel electrode 210. The pixel-defining layer 130 may include an organic insulating material and/or an inorganic insulating material. One opening 130OP in the pixel-defining layer 130 may correspond to one light-emitting element LED and may define one emission area. An area exposed by the opening 130OP of the pixel-defining layer 130 may be defined as an emission area.

The intermediate layer 220 may be disposed on the pixel-defining layer 130. The intermediate layer 220 may include an emission layer disposed in the opening 130OP of the pixel-defining layer 130. The emission layer may include a high-molecular weight or low-molecular weight organic material emitting light of a certain color.

Although not shown in FIG. 3, a first functional layer and a second functional layer may be further disposed under and on the emission layer, respectively. The first functional layer may include, for example, a hole transport layer (HTL), or an HTL and a hole injection layer (HIL). The second functional layer is an element disposed on the emission layer and is optional. The second functional layer may include an electron transport layer (ETL) and/or an electron injection layer (EIL). In an embodiment, like the opposite electrode 230 described below, the first functional layer and/or the second functional layer may be common layers entirely covering the substrate 100.

The opposite electrode 230 may include a conductive material having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 230 may further include a layer, such as ITO, IZO, ZnO, or In₂O₃, on a (semi) transparent layer including the above material.

In some embodiments, a capping layer (not shown) may be further disposed on the opposite electrode 230. The capping layer may include lithium fluoride (LiF), an inorganic material, and/or an organic material.

The encapsulation member 300 may cover the light-emitting element LED. The encapsulation member 300 may be disposed on the opposite electrode 230. In an embodiment, the encapsulation member 300 may be disposed on the display area DA.

In an embodiment, the encapsulation member 300 includes at least one inorganic encapsulation layer and at least one organic encapsulation layer, and in an embodiment, the encapsulation member 300 is shown as including a first inorganic encapsulation layer 310, the organic encapsulation layer 320, and a second inorganic encapsulation layer 330 sequentially stacked on one another.

The first inorganic encapsulation layer 310 and the second inorganic encapsulation layer 330 may be entirely disposed on the display area DA and the peripheral area PA. The first inorganic encapsulation layer 310 and the second inorganic encapsulation layer 330 may be apart from each other in the display area DA. The first inorganic encapsulation layer 310 and the second inorganic encapsulation layer 330 may be apart from each other in some regions of the peripheral area PA and may be in contact with each other in the other regions. The first inorganic encapsulation layer 310 and the second inorganic encapsulation layer 330 may be in contact with each other over the first dam portion DP1 and/or the second dam portion DP2.

The first inorganic encapsulation layer 310 and the second inorganic encapsulation layer 330 may include an inorganic material. The first inorganic encapsulation layer 310 and the second inorganic encapsulation layer 330 may include, for example, one or more inorganic materials among aluminum oxide (Al₂O₃), titanium oxide (TiO₂), tantalum oxide (Ta₂O₅), hafnium oxide (HfO₂), zinc oxide (ZnOₓ, which may include ZnO and/or ZnO₂), silicon oxide (SiO₂), silicon nitride (SiNₓ), and silicon oxynitride (SiON).

The organic encapsulation layer 320 may be disposed on the display area DA. The organic encapsulation layer 320 may extend from the display area DA to the peripheral area PA. The organic encapsulation layer 320 may fill the first valley portion VP1 and the second valley portion VP2. The organic encapsulation layer 320 may overlap the first valley portion VP1 and the second valley portion VP2. The organic encapsulation layer 320 may not overlap at least the first dam portion DP1. The organic encapsulation layer 320 may not overlap the second dam portion DP2. The organic encapsulation layer 320 may extend from the display area DA to the inside of the second dam portion DP2. The organic encapsulation layer 320 may overlap the second thin-film transistor TFT2 and/or the third thin-film transistor TFT3.

In the case where the organic encapsulation layer 320 is formed using an inkjet method, when an inkjet discharge location of an organic material is biased toward an end of the substrate 100, a material of an organic layer may overflow to the outside of the first dam portion DP1. When the inkjet discharge location of the organic material is biased toward the display area DA, the first and second inorganic encapsulation layers 310 and 330 may be cracked due to the lack of an organic material filled in the peripheral area PA. Accordingly, there is a need to monitor whether the organic material is accurately discharged to a target location and is safely disposed on the target location and to adjust a discharge location of an organic material.

As shown in FIG. 4, the organic encapsulation layer 320 may include an organic material 321 and surface-enhanced Raman scattering (SERS) active nanoparticles 400. The organic encapsulation layer 320 may be formed by adding the SERS active nanoparticles 400 into the organic material 321. The viscosity of the organic encapsulation layer 320 may range from about 1 cP to about 50 cP. Because the organic encapsulation layer 320 includes the SERS active nanoparticles 400, whether an organic encapsulation layer 320 is disposed at a target location may be tested by Raman spectroscopy or Raman detection after the organic encapsulation layer 320 is formed. Because layers disposed below the organic encapsulation layer 320, for example, the pixel-defining layer 130, the opposite electrode 230 of the light-emitting element LED, and/or the capping layer on the opposite electrode 230, do not include SERS active nanoparticles, a position of an end where the organic encapsulation layer 320 is formed may be identified by distinguishing between the organic encapsulation layer 320 and the layers disposed below the organic encapsulation layer 320.

A SERS active nanoparticle 400 may be a nanoparticle in which a Raman label compound 420 is adsorbed or bound onto a surface of a metal nanoparticle 410. The SERS active nanoparticle 400 may be a material obtained by surface-treating the metal nanoparticle 410 with the Raman label compound 420. In the present description, the Raman label compound 420 may refer to a small-molecule compound among materials that cause a Raman signal in vibrational, rotational, and other low-frequency modes of a material. The Raman signal is recognized as a structural fingerprint for a molecule and is used as a probe for detecting a target material in a sample.

The content of the SERS active nanoparticles 400 may be greater than 0 wt % but not more than about 5 wt %, based on a total weight of the organic encapsulation layer 320. When the content of the SERS active nanoparticles 400 is greater than 5 wt %, the transmittance of the organic encapsulation layer 320 may decrease.

A size of the metal nanoparticle 410 may be, for example, at least about 1 nm but not more than about 20 nm. A size of the metal nanoparticle 410 may be, for example, at least about 5 nm but not more than about 20 nm. When a size of the metal nanoparticle 410 is less than 1 nm, the Raman label compound 420 may not be well adsorbed onto the metal nanoparticle 410. When a size of the metal nanoparticle 410 is greater than 20 nm, the transmittance of the organic encapsulation layer 320 may decrease. The metal nanoparticle 410 may include, for example, a metal particle such as gold (Au), silver (Ag), or copper (Cu).

When the content of the SERS active nanoparticles 400 is greater than 0 wt % but not more than about 5 wt %, and a size of the SERS active nanoparticle 400 or the metal nanoparticle 410 included in the SERS active nanoparticle 400 is 20 nm or less, the transmittance of the organic encapsulation layer 320 may be about 97% or greater. Accordingly, even when the organic encapsulation layer 320 includes the SERS active nanoparticles 400, display quality of the display device 1 may not deteriorate.

In an embodiment, the Raman label compound 420 may include an aromatic ring. When the SERS active nanoparticle 400 includes the Raman label compound 420 including an aromatic ring, it may be easy to distinguish from the layers disposed below the organic encapsulation layer 320. The Raman label compound 420 may include, for example, at least one of thiophenol, 4-Mercaptophenol, 4-nitrothiophenol, 4-aminothiophenol, 4-mercaptophenylboronic acid, 4-mercaptobenzoic acid, or pyridine-4-thiol.

The organic material 321 may include a photocurable organic material or a thermosetting organic material. The organic material 321 may include a polymer-based material. The organic material 321 may include a photocurable monomer or a thermosetting monomer. The organic material 321 may include acryl-based resin (e.g., polymethyl methacrylate, polyacrylic acid, etc.), epoxy-based resin, polyethylene terephthalate, polyethylene naphthalate, polycarbonate, polyethylene sulfonate, polyoxymethylene, polyarylate, hexamethyldisiloxane, polyimide, polyethylene, or any combination thereof.

The display device 1 may include the first dam portion DP1 and the second dam portion DP2. The first dam portion DP1 and the second dam portion DP2 may be disposed on the peripheral area PA. The first dam portion DP1 and the second dam portion DP2 may at least partially overlap the power voltage line 11. The first dam portion DP1 may be apart from the organic encapsulation layer 320 in a first direction (e.g., a direction x or a direction y). The first dam portion DP1 may not overlap the organic encapsulation layer 320. In other words, the first dam portion DP1 may not be covered by the organic encapsulation layer 320. The second dam portion DP2 may be disposed between the first dam portion DP1 and the organic encapsulation layer 320. The second dam portion DP2 may be disposed between the first dam portion DP1 and the first valley portion VP1.

The first dam portion DP1 may include a first insulating pattern 110Pa, a second insulating pattern 120Pa, a third insulating pattern 130Pa, and a fourth insulating pattern 140Pa sequentially stacked on one another. The first insulating pattern 110Pa may be disposed on the third inorganic insulating layer 107. The second insulating pattern 120Pa may be disposed on the first insulating pattern 110Pa. The third insulating pattern 130Pa may be disposed on the second insulating pattern 120Pa. The fourth insulating pattern 140Pa may be disposed on the third insulating pattern 130Pa.

The first insulating pattern 110Pa may be formed during the same process operation as the first planarization layer 110 and may include the same material as the first planarization layer 110. The second insulating pattern 120Pa may be formed during the same process operation as the second planarization layer 120 and may include the same material as the second planarization layer 120. The third insulating pattern 130Pa may be formed during the same process operation as the pixel-defining layer 130 and may include the same material as the pixel-defining layer 130. The fourth insulating pattern 140Pa may be formed during the same process operation as a spacer (not shown) disposed on the pixel-defining layer 130 in the display area DA and may include the same material as the spacer.

The second dam portion DP2 may include a fifth insulating pattern 120Pb, a sixth insulating pattern 130Pb, and a seventh insulating pattern 140Pb sequentially stacked on one another. The fifth insulating pattern 120Pb may be disposed over the third inorganic insulating layer 107. The sixth insulating pattern 130Pb may be disposed on the fifth insulating pattern 120Pb. The seventh insulating pattern 140Pb may be disposed on the sixth insulating pattern 130Pb.

The fifth insulating pattern 120Pb may be formed during the same process operation as the second planarization layer 120 and/or the second insulating pattern 120Pa and may include the same material as the second planarization layer 120 and/or the second insulating pattern 120Pa. The sixth insulating pattern 130Pb may be formed during the same process operation as the pixel-defining layer 130 and/or the third insulating pattern 130Pa and may include the same material as the pixel-defining layer 130 and/or the third insulating pattern 130Pa. The seventh insulating pattern 140Pb may be formed during the same process operation as a spacer (not shown) disposed on the pixel-defining layer 130 in the display area DA and/or the fourth insulating pattern 140Pa and may include the same material as the spacer (not shown) and/or the fourth insulating pattern 140Pa.

The number and height of insulating patterns included in the first dam portion DP1 and the second dam portion DP2 are not limited to those shown and may vary depending on embodiments.

In the peripheral area PA, the display device 1 may further include an eighth insulating pattern 130h disposed on the second planarization layer 120. In an embodiment, the eighth insulating pattern 130h may be formed during the same process operation as the pixel-defining layer 130 and may have a height relatively smaller than that of the pixel-defining layer 130 due to a subsequent process. In an embodiment, the eighth insulating pattern 130h may be an insulating pattern disposed on the second planarization layer 120 through a separate process from the pixel-defining layer 130 of the display area DA.

The display device 1 may include the first valley portion VP1 including an opening OP1 in the first planarization layer 110 and an opening OP2 in the second planarization layer 120. The first valley portion VP1 may be disposed on the peripheral area PA. The first valley portion VP1 may be disposed between the first dam portion DP1 and the display area DA. The first valley portion VP1 may be disposed between the second dam portion DP2 and the display area DA. Portions of the first planarization layer 110 and the second planarization layer 120 in the peripheral area PA may be separated from portions thereof in the display area DA by the first valley portion VP1. The first valley portion VP1 may prevent or reduce moisture or foreign materials generated in an area disposed outside from penetrating into the display area DA through the first planarization layer 110 and/or the second planarization layer 120.

The power voltage line 11 may be disposed between the first insulating pattern 110Pa of the first dam portion DP1 and the first planarization layer 110. In an embodiment, the edge of the power voltage line 11 may be covered by the first insulating pattern 110Pa of the first dam portion DP1 and the first planarization layer 110, and a central portion of the power voltage line 11 may not be covered by the first dam portion DP1 and the first planarization layer 110 to have an exposed upper surface.

A conductive layer CLa may be disposed on the power voltage line 11. In an embodiment, the conductive layer CLa may include a first conductive layer CL1 and a second conductive layer CL2 on the first conductive layer CL1.

The first conductive layer CL1 may be disposed on an upper surface of the power voltage line 11 and may be disposed on a side surface of the first insulating pattern 110Pa and a side surface of the first planarization layer 110. In other words, the first conductive layer CL1 may be disposed on the upper surface of the power voltage line 11 and may extend to the side surface of the first insulating pattern 110Pa and the side surface of the first planarization layer 110. A portion of the first conductive layer CL1 may be disposed on an upper surface of the first insulating pattern 110Pa and an upper surface of the first planarization layer 110.

The second conductive layer CL2 may be disposed on the second valley portion VP2 described below. The second conductive layer CL2 may be disposed on an upper surface of the first conductive layer CL1 and may be disposed on a side surface of the fifth insulating pattern 120Pb and a side surface of the second planarization layer 120. In other words, the second conductive layer CL2 may be disposed on the upper surface of the first conductive layer CL1 and may extend to the side surface of the fifth insulating pattern 120Pb and the side surface of the second planarization layer 120. A portion of the second conductive layer CL2 may be disposed on an upper surface of the fifth insulating pattern 120Pb and an upper surface of the second planarization layer 120. The first inorganic encapsulation layer 310 may be disposed on the second conductive layer CL2.

A conductive pattern layer CPL may be disposed on the first valley portion VP1. The conductive pattern layer CPL may be in contact with an upper surface of the third inorganic insulating layer 107 and may extend to a side wall of the first planarization layer 110, a side wall of the second planarization layer 120, and the upper surface of the second planarization layer 120. The first inorganic encapsulation layer 310 may be disposed over the conductive pattern layer CPL.

The display device 1 may further include the second valley portion VP2 disposed between the second dam portion DP2 and the first valley portion VP1. The second valley portion VP2 may be disposed on the peripheral area PA. The second valley portion VP2 may be disposed between the first dam portion DP1 and the display area DA. The second valley portion VP2 may be disposed between the second dam portion DP2 and the display area DA. The second valley portion VP2 may be an area where the second dam portion DP2 and the first and second planarization layers 110 and 120 are apart from each other and thus the encapsulation member 300 is prevented from overflowing to the outside of the second dam portion DP2.

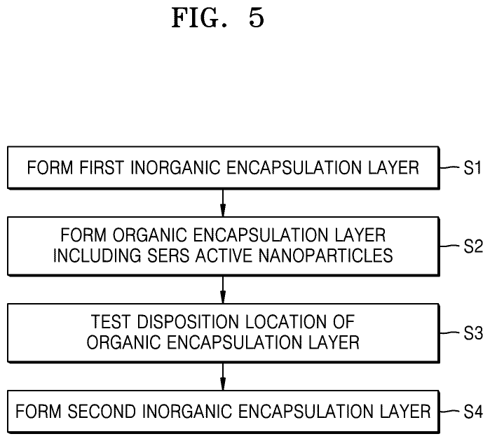

FIG. 5 is a flowchart of a method of manufacturing of a display device, according to an embodiment. In an embodiment, the display device 1 described with reference to FIGS. 3 and 4 may be formed according to the method of manufacturing a display device, described with reference to FIG. 5.

Referring to FIGS. 3 to 5, a method of manufacturing the display device 1 may include an operation of forming the first inorganic encapsulation layer 310 on the light-emitting element LED in an operation S1, an operation of forming, on the first inorganic encapsulation layer 310, the organic encapsulation layer 320 including the SERS active nanoparticles 400 in an operation S2, an operation of testing a disposition location of the organic encapsulation layer 320 in an operation S3, and an operation of forming the second inorganic encapsulation layer 330 on the organic encapsulation layer 320 in an operation S4.

Before the first inorganic encapsulation layer 310 is formed, the pixel circuit layer PCL including the pixel circuit PC may be formed on the substrate 100, and the light-emitting element LED over the pixel circuit layer PCL may be formed. In an embodiment, the first dam portion DP1 and/or the second dam portion DP2 disposed on the peripheral area PA may be formed on the pixel circuit layer PCL. The first dam portion DP1 and the second dam portion DP2 may be disposed on the periphery of the substrate 100.

The first inorganic encapsulation layer 310 may be entirely formed over the substrate 100. That is, the first inorganic encapsulation layer 310 may be entirely formed in the display area DA where the light-emitting element LED is disposed and the peripheral area PA where the light-emitting element LED is not disposed.

The first inorganic encapsulation layer 310 may be formed on the light-emitting element LED by a deposition process. For example, the first inorganic encapsulation layer 310 may be formed by chemical vapor deposition (CVD).

The first inorganic encapsulation layer 310 may include an inorganic material. The first inorganic encapsulation layer 310 may include, for example, one or more inorganic materials among aluminum oxide (Al₂O₃), titanium oxide (TiO₂), tantalum oxide (Ta₂O₅), hafnium oxide (HfO₂), zinc oxide (ZnOₓ, which may include ZnO and/or ZnO₂), silicon oxide (SiO₂), silicon nitride (SiNₓ), and silicon oxynitride (SiON).

The organic encapsulation layer 320 may be formed on the first inorganic encapsulation layer 310. The organic encapsulation layer 320 may be formed to cover the entire display area DA. The organic encapsulation layer 320 may be formed to cover only a portion of the peripheral area PA. For example, the organic encapsulation layer 320 may be formed not to overlap the first dam portion DP1. For example, the organic encapsulation layer 320 may be formed not to overlap the second dam portion DP2. For example, the organic encapsulation layer 320 may be formed not to overflow to the outside of the first dam portion DP1 and/or the second dam portion DP2.

The organic encapsulation layer 320 may include a material obtained by adding the SERS active nanoparticles 400 into an organic material. For example, the organic encapsulation layer 320 may include a material obtained by adding the SERS active nanoparticles 400 into a composition including a thermosetting or photocurable monomer. The monomer for forming the organic encapsulation layer 320 may be, for example, an acryl monomer or an epoxy monomer. The organic encapsulation layer 320 may be formed, for example, by performing an inkjet process. Based on a total weight of the organic encapsulation layer 320, the content of the SERS active nanoparticles 400 may be greater than 0 wt % but not more than 5 wt %.

The SERS active nanoparticles 400 added into the organic material may be formed through surface treatment for adsorbing or binding the Raman label compound 420 onto the metal nanoparticle 410. A size of the metal nanoparticle 410 may be, for example, at least about 1 nm but not more than about 20 nm. A size of the metal nanoparticle 410 may be, for example, at least about 5 nm but not more than about 20 nm. The metal nanoparticle 410 may include, for example, a metal particle such as gold (Au), silver (Ag), or copper (Cu). The Raman label compound 420 adsorbed onto the metal nanoparticle 410 may be a compound including an aromatic ring. For example, the Raman label compound 420 adsorbed onto the metal nanoparticle 410 may include, for example, at least one of thiophenol, 4-Mercaptophenol, 4-nitrothiophenol, 4-aminothiophenol, 4-mercaptophenylboronic acid, 4-mercaptobenzoic acid, or pyridine-4-thiol.

The organic encapsulation layer 320 includes a composition including a photocurable monomer or a thermosetting monomer, and accordingly, may include a polymer-based material formed by curing an organic material. The organic material 321 included in the organic encapsulation layer 320 may be a polymer-based material formed by curing a photocurable monomer or a thermosetting monomer. For example, the organic material 321 may include acryl-based resin (e.g., polymethyl methacrylate, polyacrylic acid, etc.), epoxy-based resin, polyethylene terephthalate, polyethylene naphthalate, polycarbonate, polyethylene sulfonate, polyoxymethylene, polyarylate, hexamethyldisiloxane, polyimide, polyethylene, or any combination thereof.

After the organic encapsulation layer 320 is formed, an operation of testing a disposition location of the organic encapsulation layer 320 may be performed. Because the organic encapsulation layer 320 includes the SERS active nanoparticles 400, a disposition location of the organic encapsulation layer 320 may be analyzed by Raman spectroscopy or Raman detection. Unlike the organic encapsulation layer 320, layers disposed below the organic encapsulation layer 320 (e.g., the pixel-defining layer 130, the opposite electrode 230, and the capping layer on the opposite electrode 230) do not include the SERS active nanoparticles 400, and accordingly, the organic encapsulation layer 320 may be identified distinguished from the layers below by using Raman spectroscopy or Raman detection. For example, it may be tested using Raman spectroscopy or Raman detection whether the organic encapsulation layer 320 covers light-emitting elements LED of the display area DA and has not overflowed to the outside of the first dam portion DP1 and/or the second dam portion DP2.

In the present description, Raman spectroscopy or Raman detection may be a method in which Raman scattering, which occurs when a material with a Raman label compound scatters involving loss or gain of molecular vibrational energy, is detected through a Raman spectrometer when a material is irradiated with a light source. Raman spectroscopy may be a method in which a SERS spectrum formed for a target material by Raman scattering is measured and analyzed. Raman spectroscopy may include an operation of irradiating a target material with a light source and an operation of detecting Raman scattering (or a Raman signal) from the target material.

The second inorganic encapsulation layer 330 may be entirely formed over the substrate 100. That is, the second inorganic encapsulation layer 330 may be entirely formed in the display area DA where the light-emitting element LED is disposed and the peripheral area PA where the light-emitting element LED is not disposed.

The second inorganic encapsulation layer 330 may be formed on the organic encapsulation layer 320 and the first inorganic encapsulation layer 310 by using a deposition process. For example, the second inorganic encapsulation layer 330 may be formed by chemical vapor deposition (CVD).

The second inorganic encapsulation layer 330 may include an inorganic material. The second inorganic encapsulation layer 330 may include, for example, one or more inorganic materials among aluminum oxide (Al₂O₃), titanium oxide (TiO₂), tantalum oxide (Ta₂O₅), hafnium oxide (HfO₂), zinc oxide (ZnOₓ, which may include ZnO and/or ZnO₂), silicon oxide (SiO₂), silicon nitride (SiNₓ), and silicon oxynitride (SiON).

According to one or more of the above embodiments, a disposition location of a material for forming an organic encapsulation layer may be monitored via Raman detection by adding SERS active nanoparticles to an organic encapsulation layer. It may be easily checked whether the organic encapsulation layer has been formed at a target location, and thus, the reliability of a display device may be increased. However, such an effect is an example, and one or more embodiments are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate comprising a display area and a peripheral area disposed outside the display area;
a light-emitting element disposed on the display area of the substrate; and
an encapsulation member disposed on the light-emitting element and comprising at least one inorganic encapsulation layer and at least one organic encapsulation layer,
wherein an organic encapsulation layer of the at least one organic encapsulation layer comprises surface-enhanced Raman scattering (SERS) active nanoparticles.

2. The display device of claim 1, wherein the SERS active nanoparticles are metal nanoparticles on the surface of which a Raman label compound is adsorbed,
wherein a size of each of the metal nanoparticles is at least 1 nm but not more than 20 nm.

3. The display device of claim 2, wherein the metal nanoparticles comprise gold (Au), silver (Ag), or copper (Cu).

4. The display device of claim 2, wherein the Raman label compound comprises an aromatic ring.

5. The display device of claim 4, wherein the Raman label compound comprises at least one of thiophenol, 4-Mercaptophenol, 4-nitrothiophenol, 4-aminothiophenol, 4-mercaptophenylboronic acid, 4-mercaptobenzoic acid, or pyridine-4-thiol.

6. The display device of claim 1, wherein, based on a total weight of the organic encapsulation layer, a content of the SERS active nanoparticles is greater than 0 wt % but not more than 5 wt %.

7. The display device of claim 1, wherein a viscosity of the organic encapsulation layer ranges from 1 cP to 50 cP.

8. The display device of claim 1, wherein the at least one inorganic encapsulation layer comprises a first inorganic encapsulation layer and a second inorganic encapsulation layer, the organic encapsulation layer being disposed on the first inorganic encapsulation layer, and the second inorganic encapsulation layer being disposed on the organic encapsulation layer.

9. The display device of claim 8, further comprising a dam portion disposed on the peripheral area,
wherein the first inorganic encapsulation layer and the second inorganic encapsulation layer are in contact with each other on the dam portion.

10. The display device of claim 9, further comprising a valley portion disposed on the peripheral area and disposed between the dam portion and the display area,
wherein the organic encapsulation layer overlaps the valley portion.

11. The display device of claim 1, wherein the light-emitting element comprises a pixel electrode, an emission layer on the pixel electrode, and an opposite electrode on the emission layer.

12. A display device comprising:
a substrate;
a light-emitting element disposed on the substrate and comprising a pixel electrode, an emission layer on the pixel electrode, and an opposite electrode on the emission layer; and
an encapsulation member disposed on the light-emitting element and comprising a first inorganic encapsulation layer, an organic encapsulation layer on the first inorganic encapsulation layer, and a second inorganic encapsulation layer on the organic encapsulation layer,
wherein the organic encapsulation layer comprises surface-enhanced Raman scattering (SERS) active nanoparticles in which metal nanoparticles are surface-treated with a Raman label compound,
wherein the Raman label compound comprises an aromatic ring.

13. The display device of claim 12, wherein a size of each of the metal nanoparticles is 20 nm or less.

14. The display device of claim 12, wherein the metal nanoparticles comprise gold (Au), silver (Ag), or copper (Cu).

15. The display device of claim 12, wherein the Raman label compound comprises at least one of thiophenol, 4-Mercaptophenol, 4-nitrothiophenol, 4-aminothiophenol, 4-mercaptophenylboronic acid, 4-mercaptobenzoic acid, or pyridine-4-thiol.

16. The display device of claim 12, wherein based on a total weight of the organic encapsulation layer, a content of the SERS active nanoparticles is greater than 0 wt % but not more than 5 wt %.

17. A method of manufacturing a display device, the method comprising:
forming a first inorganic encapsulation layer on a light-emitting element;
forming an organic encapsulation layer on the first inorganic encapsulation layer, the organic encapsulation layer comprising surface-enhanced Raman scattering (SERS) active nanoparticles;
testing a disposition location of the organic encapsulation layer by using Raman spectroscopy; and
forming a second inorganic encapsulation layer on the organic encapsulation layer.

18. The method of claim 17, wherein the SERS active nanoparticles are formed by surface-treating metal nanoparticles with a Raman label compound,
wherein a size of each of the metal nanoparticles is 20 nm or less.

19. The method of claim 18, wherein the Raman label compound comprises an aromatic ring.

20. The method of claim 18, wherein the Raman label compound comprises at least one of thiophenol, 4-Mercaptophenol, 4-nitrothiophenol, 4-aminothiophenol, 4-mercaptophenylboronic acid, 4-mercaptobenzoic acid, or pyridine-4-thiol.
